(19) United States
(12) Patent Application Publication
(10) Pub. No.: US 2023/0341764 A1
(43) Pub. Date: Oct. 26, 2023

(54) NANOFIBER FILM TENSION CONTROL

(71) Applicant: LINTEC OF AMERICA, INC., Plano, TX (US)

(72) Inventors: Marcio D. LIMA, Richardson, TX (US); Takahiro UEDA, Frisco, TX (US)

(73) Assignee: LINTEC OF AMERICA, INC., Plano, TX (US)

(21) Appl. No.: 18/026,722

(22) PCT Filed: Sep. 16, 2021
(86) PCT No.: PCT/US2021/050654

§ 371 Date: Mar. 16, 2023

Related U.S. Application Data
(60) Provisional application No. 63/079,672, filed on Sep. 17, 2020.

(51) Int. Cl. G03F 1/64

(52) U.S. Cl. CPC G03F 1/64

(57) ABSTRACT

An apparatus and method are described herein for providing tension to carbon nanotube films. An apparatus and method are described herein for transferring carbon nanotube films from a first frame to a second frame. An example method includes deforming a frame by one of a thermal method or a physical method, allowing the frame to return to an original shape, and providing tension to the carbon nanotube film.

### TECHNICAL FIELD

The present disclosure relates generally to carbon nanofiber films. Specifically, the present disclosure relates to an apparatus and methods for controlling tension in a nanofiber film.

### BACKGROUND

Nanofibers are known to have unusual mechanical, optical, and electronic properties. Nanofiber sheets or films of nanofibers may be prepared by various methods. However, devising configurations of nanofiber sheets that can be integrated into commercial products has been challenging because of the nanoscale dimensions of the nanofibers, their structures, interactions, and physical properties. For example, nanofibers can be arranged with a particular orientation or a random fashion. Nanofiber sheets can also be treated in various ways enhancing their properties and targeting different applications.

### SUMMARY

In a first example, a method includes positioning a carbon nanotube membrane on a first frame, positioning a second frame on the carbon nanotube membrane, transferring the carbon nanotube membrane to the second frame, providing a first deformation to the second frame, and providing a second deformation to the second frame.

Example 2 includes the subject matter of Example 1, wherein the first deformation comprises shrinking.

Example 3 includes the subject matter of Example 2, wherein the second deformation comprises enlarging.

Example 4 includes the subject matter of Example 1, wherein at least one of the first deformation and the second deformation change the size of the second frame by between 0.5% and 5% with respect to width, length, diameter, or perimeter of the frame.

Example 5 includes the subject matter of Example 2, wherein the first deformation comprises cooling the second frame.

Example 6 includes the subject matter of Example 3, wherein the second deformation comprises warming the second frame.

Example 7 includes the subject matter of Example 2, wherein the first deformation comprises utilizing a set of pins attached to the second frame that are pushed or pulled inward.

Example 8 includes the subject matter of either of Example 3, wherein the second deformation comprises utilizing a set of pins attached to the second frame that are pushed or pulled outward.

Example 9 includes the subject matter of Example 1, wherein transferring the carbon nanotube membrane to the second frame is achieved by lifting the first frame off of the carbon nanotube membrane.

Example 10 includes the subject matter of Example 1, wherein transferring the carbon nanotube membrane to the second frame is achieved by sliding the first frame past the second frame.

Example 12 includes the subject matter of Example 1, wherein the carbon nanotube membrane is configured with increased tension following the first deformation and the second deformation.

Example 13 includes the subject matter of Example 12, wherein the carbon nanotube membrane is configured with decreased deflection following the first deformation and the second deformation.

Example 14 includes the subject matter of any of the preceding Examples, wherein the carbon nanotube membrane is a carbon nanotube filtered film.

### BRIEF DESCRIPTION OF THE DRAWINGS

FIG. 1 is a photomicrograph of an example forest of nanofibers on a substrate, in accordance with an embodiment of the disclosure.

FIG. 2 is a schematic illustration of an example reactor for nanofiber growth, in accordance with an embodiment of the disclosure.

FIG. 3 is an illustration of a nanofiber sheet that identifies relative dimensions of the sheet and schematically illustrates nanofibers within the sheet aligned end-to-end in a plane parallel to a surface of the sheet, in accordance with an embodiment of the disclosure.

FIG. 4 is a scanning electron microscopy (SEM) image of a nanofiber sheet being laterally drawn from a nanofiber forest, the nanofibers aligning from end-to-end as schematically, in accordance with an embodiment of the disclosure.

FIG. 5 is a flow chart illustrating steps in a method for transferring a carbon nanotube membrane from a first frame to a second frame, in accordance with an embodiment of the disclosure.

FIG. 6A is a cross-sectional side view of an example carbon nanotube membrane positioned on a first frame, in accordance with an embodiment of the disclosure.

FIG. 6B is a cross-sectional side view of an example carbon nanotube membrane positioned on a first frame and a second frame, in accordance with an embodiment of the disclosure.

FIG. 6C is a cross-sectional side view of an example carbon nanotube membrane positioned on a second frame, with a less dense edge portion remaining on a first frame, in accordance with an embodiment of the disclosure.

FIG. 7 is a flow chart illustrating steps in a method for transferring a coated carbon nanotube membrane from a first frame to a second frame, in accordance with an embodiment of the disclosure.

FIG. 8A is a cross-sectional side view of an example carbon nanotube membrane positioned on a first frame, in accordance with an embodiment of the disclosure.

FIG. 8B is a cross-sectional side view of an example carbon nanotube membrane positioned on a first frame and a second frame, in accordance with an embodiment of the disclosure.

FIG. 8C is a cross-sectional side view of an example carbon nanotube membrane positioned on a second frame, in accordance with an embodiment of the disclosure.

FIG. 9 is a schematic illustration of a portion of a filtered nanotube film that includes larger and longer multiwall carbon nanofibers intermixed with single wall and/or few wall carbon nanotubes, all of which are randomly oriented within a plane of the film, in accordance with an embodiment of the disclosure.

FIG. 10 is a cross-sectional side view of an example nanofiber membrane of the present disclosure, the cross-section taken perpendicular to major surfaces of the membrane, in accordance with an embodiment of the disclosure.

FIG. 11 is a cross-sectional side view of an example nanofiber membrane of the present disclosure, the cross-section taken perpendicular to major surfaces of the membrane, in accordance with an embodiment of the disclosure.

FIG. 12 is a flow chart illustrating steps of conformal coating of nanofiber membrane post membrane transfer in accordance with an embodiment of the disclosure.

FIG. 13 illustrates an example method for controlling tension of a nanofiber membrane, in accordance with an embodiment of the disclosure.

FIGS. 14A-C illustrate cross-sectional side views of an example carbon nanotube membrane on a frame, in accordance with an embodiment of the disclosure.

FIGS. 15A-C illustrate cross-sectional side view of an example carbon nanotube membrane on a frame, in accordance with an embodiment of the disclosure.

The figures depict various embodiments of the present disclosure for purposes of illustration only. Numerous variations, configurations, and other embodiments will be apparent from the following detailed discussion.

### DETAILED DESCRIPTION

### Overview

Described herein is an apparatus and method for controlling tension in a nanofiber membrane. A nanofiber membrane is transferred from a first frame to a second frame. The second frame is deformed by one of cooling the frame or mechanically applying force to the frame.

Techniques are described for transferring a nanofiber film from a first frame to a second frame. In some embodiments, the nanofiber film is transferred by contact from a first frame to a second frame. In some embodiments, the nanofiber film is transferred by sliding a first frame past a second frame. Films may be coated conformally with a material as described in greater detail below.

The nanofiber film disclosed herein may comprise multiwall carbon nanotubes (MWCNT), few wall carbon nanotubes (FWCNT), or single wall carbon nanotubes (SWCNT), or a combination thereof. In some embodiments, the nanofiber film, or filtered film, may be a multi-layer film comprising layers each comprising exclusively multiwall carbon nanotubes (MWCNT), few wall carbon nanotubes (FWCNT), double wall carbon nanotubes (DWCNT), or single wall carbon nanotubes (SWCNT).

### Multiwall, Few Wall, and Single Wall Carbon Nanotubes

The processes used to form pure forms of multiwall carbon nanotubes (e.g., carbon nanotubes having from 4 to 20 concentric walls and a diameter of from 4 nm to 100 nm), few wall carbon nanotubes (e.g., carbon nanotubes having two or three concentric walls and a diameter of from 2 nm to 6 nm), and single wall carbon nanotubes (e.g., 1 wall and a tube diameter of from 0.2 nm to 4 nm) can differ from one another. For example, while multiwall carbon nanotubes can be fabricated using a chemical vapor deposition process on a relatively thick layer of catalyst (e.g., from 10 nm to several microns thick) on a substrate, few and single wall carbon nanofibers are often formed using laser ablation, carbon arc processes, or chemical vapor deposition on a thin layer of catalyst (e.g., 0.2 nm to 10 nm thickness) which may be discontinuous across the substrate. Laser ablation generally produces shorter carbon nanotubes than those produced by chemical vapor deposition and may produce nanotubes with fewer crystallographic defects. For at least this reason, generally the processes used to produce one type of nanofiber do not produce measurable amounts of the other types of nanofibers.

Each of these three different types of carbon nanotubes has different properties. In one example, few wall carbon nanotubes and single wall carbon nanotubes can be more conveniently dispersed in a solvent (i.e., with the majority of nanotubes suspended individually and not adsorbed onto other nanotubes) for subsequent formation into a sheet of randomly oriented carbon nanotubes. This ability of individual nanotubes to be uniformly dispersed in a solvent can in turn produce a dimensionally uniform nanotube film formed by removing the solvent from the suspended nanofibers by a filtration process. This configuration of nanofiber sheet is sometimes referred to as a “filtered film.” This physical uniformity (further improved by stacking multiple filtered films on one another) can also improve the uniformity of the properties across the film (e.g., transparency to radiation).

The strength of van der Waals attraction between nanofibers also differs between single/few wall nanofibers and multiwall nanofibers. Generally, single/few wall nanofibers have a greater van der Waals attraction to each other than that observed for multiwall nanofibers. This increased attraction between single/few wall nanofibers can improve the ability of few/single wall carbon nanotubes to adhere to one another to form a coherent, uniform nanofiber structure, such as a filtered film. The sheets or films formed from single wall carbon nanotubes and few wall carbon nanotubes are able to conform to a topography of an underlying surface at smaller dimensions than sheets or films formed from multiwall carbon nanotubes. In some examples, sheets or films formed from single wall carbon nanotubes and/or few wall carbon nanotubes can conform to a topography of an underlying substrate as small as 10 nm, which is at least 50% smaller than the feature size a multiwall carbon nanotube film can conform to because of the larger diameter of multiwall carbon nanotubes. In some cases, the multiwall carbon nanotubes are more likely than single/few wall nanotubes to agglomerate together and thereby produce a structurally non-uniform film that is less likely to conform and/or adhere to an underlying surface.

Filtered films, particularly those made with single and/or few wall carbon nanotubes also generally have greater transparency to some wavelengths of radiation, especially having a low areal density of nanofibers (e.g., 02 µg/cm²). In some examples, transmittance of incident radiation can be as high as above 90% or above 95%. In some cases, this transmittance is significantly higher than that observed in drawn sheets of multiwall carbon nanotubes (such as those drawn from a carbon nanotube forest, described below). While not wishing to be bound by theory, it is believed that the aligned orientation of nanotubes in a drawn sheet increases scattering of the radiation relative to a filtered film. In part, the greater transparency of filtered films (with their randomly oriented nanotubes) has prompted interest in forming transparent filters and pellicles from filtered carbon nanotube films in a variety of applications, including extreme ultraviolet (EUV) lithography.

Despite the advantages of single wall carbon nanotubes and few wall carbon nanotubes described above, multiwall carbon nanotubes also have advantages not necessarily observed to the same degree in nanotube structures formed from single or few wall nanotubes. For examples, structures formed from multiwall carbon nanotubes are generally observed to have greater emissivity than those formed from few/single wall carbon nanotubes. While not wishing to be bound by theory, it is believed that the greater number of walls and greater diameter of multiwall carbon nanotubes are factors in the increased emissivity. For example, multiwall carbon nanotube structures (e.g., the nanotube forest, a nanotube sheet) have a greater thermal emissivity than nanotube structures formed from few/single wall nanotubes. In one comparative example, an emissivity of a nanofiber structure comprising multiwall carbon nanotubes is on the order of 0.275 (+/- 15%) whereas a nanofiber structure comprising single wall carbon nanotubes can have a significantly lower emissivity of 0.05 (+/- 15%). High emissivity can be particularly advantageous in technological applications in which processes can cause heating within the nanofiber structure, but mechanisms of conductive or convective cooling of the nanofiber structure are limited or not technically feasible.

Thus, in accordance with some examples of the present disclosure, multilayer carbon nanofiber structures (e.g., multilayer structures comprising multiple stacked films and/or sheets) are described that are composites of multiwall carbon nanotubes and one or more of single wall and/or few walled carbon nanotubes. In some cases, the composites are stacks of one or more filtered nanofiber films and one or more drawn nanofiber sheets. In some cases, the drawn nanofiber sheet elements can be partially densified and joined to a filtered film by brief exposure (1 second, 2 seconds, 3 seconds) to solvent steam.

### Nanofiber Forests

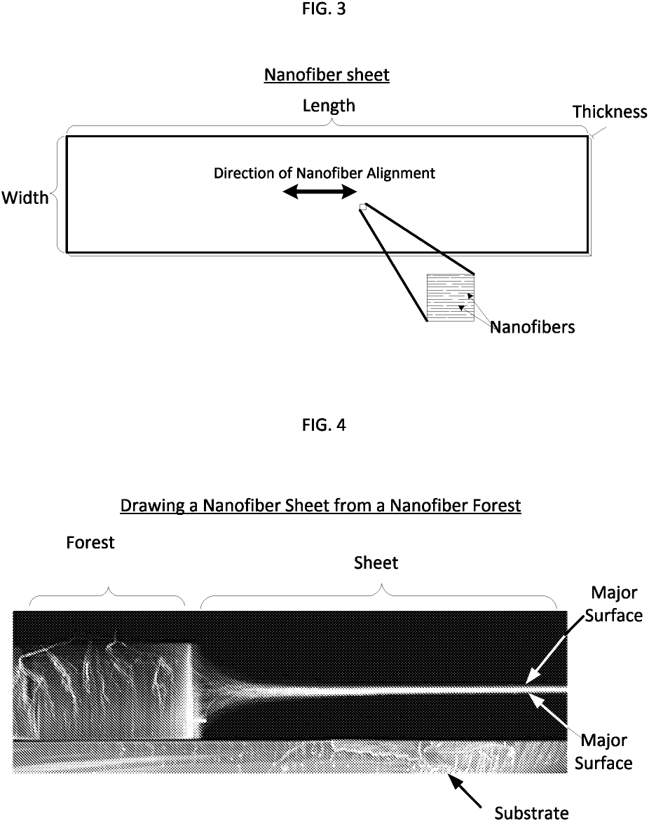

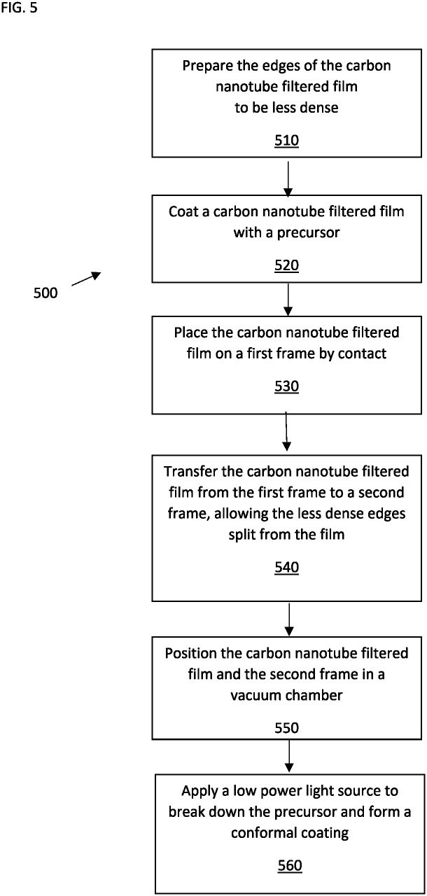

As used herein, the term “nanofiber” means a fiber having a diameter less than 1 µm. While the embodiments herein are primarily described as fabricated from carbon nanotubes, it will be appreciated that other carbon allotropes, whether graphene, micron or nano-scale graphite fibers and/or plates, and even other compositions of nano-scale fibers such as boron nitride may be included as well. As used herein, the terms “nanofiber” and “carbon nanotube” encompass both single walled carbon nanotubes and/or multi-walled carbon nanotubes in which carbon atoms are linked together to form a cylindrical structure. In some embodiments, carbon nanotubes as referenced herein have between 4 and 10 walls. As used herein, a “nanofiber sheet” or simply “sheet” refers to a sheet of nanofibers aligned via a drawing process (as described in PCT Publication No. WO 2007/015710, and incorporated by reference herein in its entirety) so that a longitudinal axis of a nanofiber of the sheet is parallel to a major surface of the sheet and a direction of drawing from a forest to a sheet, rather than perpendicular to the major surface of the sheet (i.e., in the as-deposited form of the sheet, often referred to as a “forest”). This is illustrated and shown in FIGS. 3 and 4, respectively.

The dimensions of carbon nanotubes can vary greatly depending on production methods used. For example, the diameter of a carbon nanotube may be from 0.4 nm to 100 nm and its length may range from 10 µm to greater than 55.5 cm. Carbon nanotubes are also capable of having very high aspect ratios (ratio of length to diameter) with some as high as 132,000,000:1 or more. Given the wide range of dimensional possibilities, the properties of carbon nanotubes are highly adjustable, or “tunable.” While many intriguing properties of carbon nanotubes have been identified, harnessing the properties of carbon nanotubes in practical applications requires scalable and controllable production methods that allow the features of the carbon nanotubes to be maintained or enhanced.

Due to their unique structure, carbon nanotubes possess particular mechanical, electrical, chemical, thermal and optical properties that make them well-suited for certain applications. In particular, carbon nanotubes exhibit superior electrical conductivity, high mechanical strength, good thermal stability and are also hydrophobic. In addition to these properties, carbon nanotubes may also exhibit useful optical properties. For example, carbon nanotubes may be used in light-emitting diodes (LEDs) and photo-detectors to emit or detect light at narrowly selected wavelengths. Carbon nanotubes may also prove useful for photon transport and/or phonon transport.

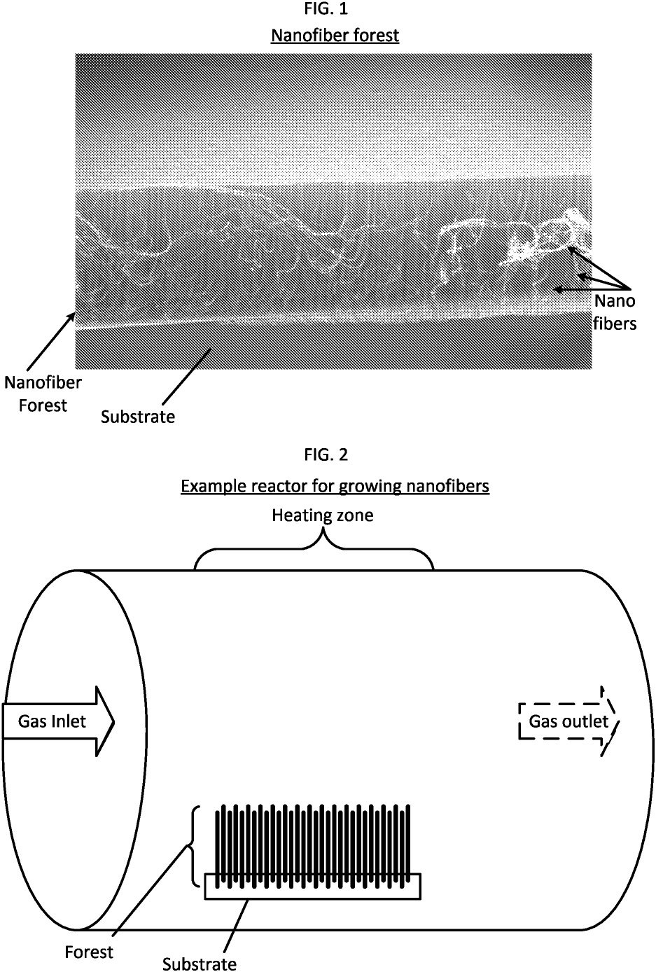

In accordance with various embodiments of the subject disclosure, nanofibers (including but not limited to carbon nanotubes) can be arranged in various configurations, including in a configuration referred to herein as a “forest.” Carbon nanotubes can be obtained from processes including the growth of nanofiber forests. As used herein, a “forest” of nanofibers or carbon nanotubes refers to an array of nanofibers having approximately equivalent dimensions that are arranged substantially parallel to one another on a substrate. FIG. 1 shows an example forest of nanofibers on a substrate. The substrate may be any shape but in some embodiments the substrate has a planar surface on which the forest is assembled. As can be seen in FIG. 1, the nanofibers in the forest may be approximately equal in height and/or diameter.

Nanofiber forests as disclosed herein may be relatively dense. Specifically, the disclosed nanofiber forests may have a density of at least 1 billion nanofibers/cm². In some specific embodiments, a nanofiber forest as described herein may have a density of between 10 billion/cm² and 30 billion/cm². In other examples, the nanofiber forest as described herein may have a density in the range of 90 billion nanofibers/cm². The forest may include areas of high density or low density and specific areas may be void of nanofibers. The nanofibers within a forest may also exhibit inter-fiber connectivity. For example, neighboring nanofibers within a nanofiber forest may be attracted to one another by van der Waals forces. Regardless, a density of nanofibers within a forest can be increased by applying techniques described herein.

Various methods can be used to produce nanofiber primary forests. For example, in some embodiments nanofibers may be grown in a high-temperature furnace, schematically illustrated in FIG. 2. In some embodiments, catalyst may be deposited on a substrate, placed in a reactor and then may be exposed to a fuel compound that is supplied to the reactor. Substrates can withstand temperatures of greater than 800° C. or even 1000° C. and may be inert materials. The substrate may comprise stainless steel or aluminum disposed on an underlying silicon (Si) wafer, although other ceramic substrates may be used in place of the Si wafer (e.g., alumina, zirconia, SiO₂, glass ceramics). In examples where the nanofibers of the primary forest are carbon nanotubes, carbon-based compounds, such as acetylene, may be used as fuel compounds. After being introduced to the reactor, the fuel compound(s) may then begin to accumulate on the catalyst and may assemble by growing upward from the substrate to form a forest of nanofibers. The reactor also may include a gas inlet where fuel compound(s) and carrier gasses may be supplied to the reactor and a gas outlet where expended fuel compounds and carrier gases may be released from the reactor. Examples of carrier gases include hydrogen, argon, and helium. These gases, in particular hydrogen, may also be introduced to the reactor to facilitate growth of the nanofiber forest. Additionally, dopants to be incorporated in the nanofibers may be added to the gas stream.

In a process used to fabricate a multilayered nanofiber forest, one nanofiber forest is formed on a substrate followed by the growth of a second nanofiber forest in contact with the first nanofiber forest. Multi-layered nanofiber forests can be formed by numerous suitable methods, such as by forming a first nanofiber forest on the substrate, depositing catalyst on the first nanofiber forest and then introducing additional fuel compound to the reactor to encourage growth of a second nanofiber forest from the catalyst positioned on the first nanofiber forest. Depending on the growth methodology applied, the type of catalyst, and the location of the catalyst, the second nanofiber layer may either grow on top of the first nanofiber layer or, after refreshing the catalyst, for example with hydrogen gas, grow directly on the substrate thus growing under the first nanofiber layer. Regardless, the second nanofiber forest can be aligned approximately end-to-end with the nanofibers of the first nanofiber forest although there is a readily detectable interface between the first and second forest. Multi-layered nanofiber forests may include any number of forests. For example, a multi-layered primary forest may include two, three, four, five or more forests.

### Nanofiber Sheets

In addition to arrangement in a forest configuration, the nanofibers of the subject application may also be arranged in a sheet configuration. As used herein, the term “nanofiber sheet,” “nanotube sheet,” or simply “sheet” refers to an arrangement of nanofibers where the nanofibers may be aligned end to end in a plane. An illustration of an example nanofiber sheet is shown in FIG. 3 with labels of the dimensions. In some embodiments, the sheet has a length and/or width that is more than 100 times greater than the thickness of the sheet. In some embodiments, the length, width or both, are more than 10³, 10⁶ or 10⁹ times greater than the average thickness of the sheet. A nanofiber sheet can have a thickness of, for example, between approximately 5 nm and 30 µm and any length and width that are suitable for the intended application. In some embodiments, a nanofiber sheet may have a length of between 1 cm and 10 meters and a width between 1 cm and 1 meter. These lengths are provided merely for illustration. The length and width of a nanofiber sheet are constrained by the configuration of the manufacturing equipment and not by the physical or chemical properties of any of the nanotubes, forest, or nanofiber sheet. For example, continuous processes can produce sheets of any length. These sheets can be wound onto a roll as they are produced.

As can be seen in FIG. 3, the axis in which the nanofibers are aligned end-to end is referred to as the direction of nanofiber alignment. In some embodiments, the direction of nanofiber alignment may be continuous throughout an entire nanofiber sheet. Nanofibers are not necessarily perfectly parallel to each other and it is understood that the direction of nanofiber alignment is an average or general measure of the direction of alignment of the nanofibers.

Nanofiber sheets may be assembled using any type of suitable process capable of producing the sheet. In some example embodiments, nanofiber sheets may be drawn from a nanofiber forest. An example of a nanofiber sheet being drawn from a nanofiber forest is shown in FIG. 4

As can be seen in FIG. 4, the nanofibers may be drawn laterally from the forest and then align end-to-end to form a nanofiber sheet. In embodiments where a nanofiber sheet is drawn from a nanofiber forest, the dimensions of the forest may be controlled to form a nanofiber sheet having particular dimensions. For example, the width of the nanofiber sheet may be approximately equal to the width of the nanofiber forest from which the sheet was drawn. Additionally, the length of the sheet can be controlled, for example, by concluding the draw process when the desired sheet length has been achieved.

Nanofiber sheets have many properties that can be exploited for various applications. For example, nanofiber sheets may have tunable opacity, high mechanical strength and flexibility, thermal and electrical conductivity, and may also exhibit hydrophobicity. Given the high degree of alignment of the nanofibers within a sheet, a nanofiber sheet may be extremely thin. In some examples, a nanofiber sheet is on the order of approximately 10 nm thick (as measured within normal measurement tolerances), rendering it nearly two-dimensional. In other examples, the thickness of a nanofiber sheet can be as high as 200 nm or 300 nm. As such, nanofiber sheets may add minimal additional thickness to a component.

As with nanofiber forests, the nanofibers in a nanofibers sheet may be functionalized by a treatment agent by adding chemical groups or elements to a surface of the nanofibers of the sheet and that provide a different chemical activity than the nanofibers alone. Functionalization of a nanofiber sheet can be performed on previously functionalized nanofibers or can be performed on previously unfunctionalized nanofibers. Functionalization can be performed using any of the techniques described herein including, but not limited to CVD, and various doping techniques.

Nanofiber sheets, as-drawn from a nanofiber forest, may also have high purity, wherein more than 90%, more than 95% or more than 99% of the weight percent of the nanofiber sheet is attributable to nanofibers, in some instances. Similarly, the nanofiber sheet may comprise more than 90%, more than 95%, more than 99% or more than 99.9% by weight of carbon.

### Nanofiber Film Coating and Formation Techniques

As described above, examples described herein include nanofiber films formed from a combination of multiwalled carbon nanotubes and one or both of single wall and few wall carbon nanotubes. These can be described as “composite films” due to the combination or mixture of different nanofiber types within a layer of a stack and/or layers composed of differently oriented nanofibers (e.g., randomly oriented filtered films, drawn sheets of aligned nanofibers). In some examples, the relative weight proportion in one type of filtered film layer is a maximum of 80 weight (wt.) % multiwalled carbon nanotubes and a minimum of 20 wt. % single and/or few wall nanotubes. Lengths of the multiwalled carbon nanotubes can be controlled by lengthening or shortening the growth process in the chemical vapor deposition reactor, as described above. But for examples herein, a multiwalled carbon nanotube length can have a median length of approximately 300 µm (+/-10%). As will be appreciated in light of the following description, multiwalled carbon nanotubes having a length of at least 250 µm or longer can be included in a filtered film to improve the mechanical stability of filtered films that also include single wall and/or few wall carbon nanotubes, which generally are shorter (e.g. from 0.5 µm to 30 µm). Films that include either the longer multiwalled nanotubes or shorter few/single wall carbon nanotubes are generally not as durable as those that include a mixture of the multiwall and few/single wall nanotubes.

FIG. 5 illustrates an example method 500 for transferring a carbon nanotube filtered film from a first frame, transfer frame, or a harvester frame, to a second frame, or final frame, by contact, and positioning the carbon nanotube filtered film and second frame in a vacuum chamber to break down a precursor to form a conformal coating. In a first step 510, the edges of the carbon nanotube filtered film are prepared to be less dense than a central portion of the carbon nanotube filtered film. In a second step 520, the carbon nanotube filtered film is coated with a coating material. In a third step 530, the carbon nanotube filtered film is placed on a first frame by contact. In a fourth step 540, the carbon nanotube filtered film is transferred from the first frame to a second frame, allowing the less dense edges to split from the film without causing damage to the central portion of the carbon nanotube filtered film. In a fifth step 550, the carbon nanotube filtered film is positioned in a vacuum. In a sixth step 560, a source of energy is applied to break down the coating material and form a conformal coating on the surfaces of nanofibers. In some examples, a conformal coating on exposed surfaces of the carbon nanofiber filtered film can reduce degradation of the filtered film caused by hydrogen ions present in a lithography exposure chamber.

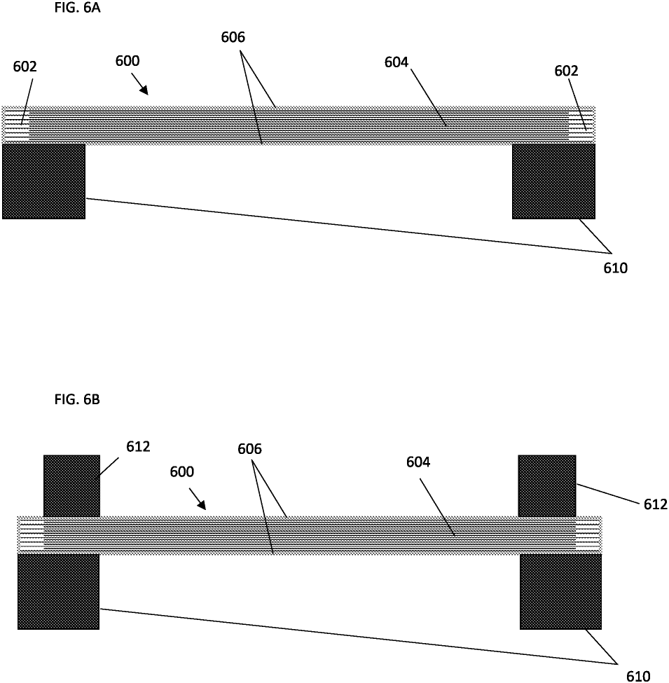

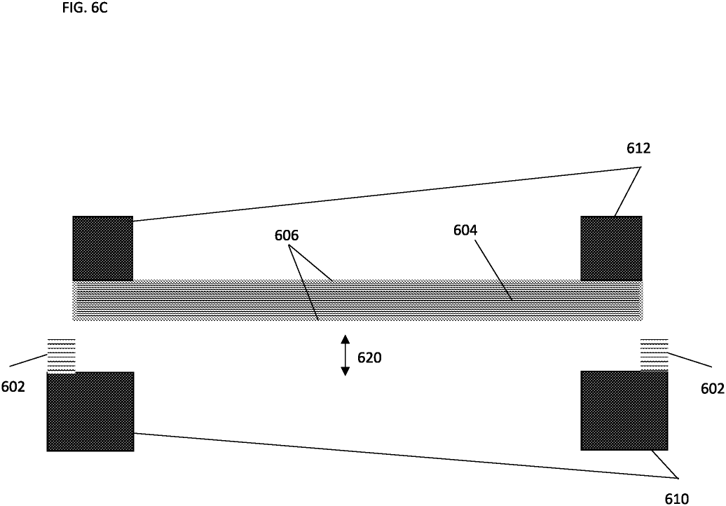

It will be appreciated that any filtered film, carbon nanotube composite, or pellicle within the scope of the disclosure can be placed on a first frame 610, 810 and transferred to a second frame 612, 812, as shown in FIGS. 6A-C and 8A-C. In some embodiments, the dimensions of first frame 610, 810 may be as close to the dimensions of second frame 612, 812 without being the same or smaller. In some examples, the frame 804 can be fabricated from polymers such as polyethylene, polycarbonate, composite materials such as carbon fiber epoxy composites, and metals such as aluminum and stainless steel. In some examples, the frame 610, 612, 810, 812 is dimensioned and configured to fit within an EUV lithography machine so that lithographically defined features can be exposed onto an underlying photoactive surface. In some examples the frame 610, 612, 810, 812 is dimensioned and configured for convenient transportation from a carbon nanotube composite manufacturing site to an EUV lithography site. In this example, the frame 610, 612, 810, 812 is configured primarily to hold a freestanding carbon nanotube film, as described herein, and conveniently release the freestanding pellicle for subsequent placement on a different frame that is configured for insertion into the EUV lithography machine. In some examples, having separate transportation and lithography frames enables the transportation frame to be fabricated according to design criteria that are easier to meet and with materials that are less expensive than those typically used when fabricating components of an EUV lithography machine. Furthermore, frames configured specifically for the EUV lithography machine, which are likely to more expensive, can be maintained solely within the lithography manufacturing location (e.g., a cleanroom), reducing the rate of wear, breakage, and/or contamination.

Carbon nanotube filtered film 600 as depicted in FIGS. 6A-C illustrates one example embodiment of transferring from a first frame to a second frame. Carbon nanotube filtered film is transferred from first frame 610 to second frame 612, by contact.

FIG. 6A is a cross-sectional side view of an example carbon nanotube membrane positioned on a first frame, in an embodiment. FIG. 6A illustrates an assembly that includes a first frame 610 on which is disposed an example carbon nanotube filtered film 600. Another exemplary carbon nanotube membrane may be a single or multiple layered drawn nanotube sheet(s). Carbon nanotube filtered film 600 includes a central more dense region 604 and a peripheral less dense region 602. A carbon nanotube filtered film, such as described in this example configuration, can be formed by a filtration process.

The filtered film can be configured to match the exposed area of the first frame 610. An outer portion of the filtered film spanning structures of the frame 610 can be removed but not the rest portion of the filtered film spanning structure of the frame 610 and the film spans an opening (or openings) within the first frame 610. Techniques to remove excess film from areas that are not directly overlying the frame 610 include using a laser, electrical discharge machine (EDM), mechanical techniques (cutting with the blade such as a surgical blade or a fracture surface of a silicon wafer). In some techniques, a solvent can be mechanically applied using an applicator such as a thin bar. For example, acetone, IPA, NMP, DMF, toluene, or other solvent (and combinations thereof) can be applied to a bar which is then passed through the film to excise the desired portion of the filtered film.

In some embodiments, the filtered film may be processed into an adhesion layer by exposing the film on the first frame 610 to a steam (i.e., vapor droplets at a temperature above boiling) of water, IPA, or a combination thereof. Exposure to the steam will cause the filtered film to adhere tightly to the first frame 610, thus forming an adhesion layer. In some examples, a bottom layer of the filtered film can be formulated so as to include a greater percentage (e.g., greater than 50%, greater than 60%, greater than 70%) of few wall and/or single wall carbon nanotubes to further improve adhesion.

FIG. 6B is a cross-sectional side view of an example carbon nanotube membrane positioned on a first frame and a second frame, in an embodiment. In FIG. 6B, second frame 612 has been positioned to be in contact with carbon nanotube filtered film 600 on a top major surface while first frame 610 remains in contact with carbon nanotube filtered film 600 on a bottom major surface. Second frame 612 is positioned on top of more dense region 604 and does not make contact with less dense region 602, in the illustrated embodiment.

FIG. 6C is a cross-sectional side view of an example carbon nanotube membrane positioned on a second frame, with a less dense edge portion remaining on a first frame, in an embodiment. In FIG. 6C, second frame 612 has been moved along direction 620 away from first frame 610. During movement along direction 620, more dense region 604 maintains contact with second frame 612 while less dense region 602 tears from carbon nanotube filtered film 600 and is maintained on first frame 610.

In some examples, as described above, a selected coating material is coated onto the carbon nanotube filtered film. Second frame 612 and carbon nanotube filtered film 600 may be placed in a vacuum chamber in line with an energy source. The applied energy source breaks down the coating material and create a conformal coating on the filtered film.

FIG. 12 illustrates an alternative process for a conformal coating of a nanofiber membrane 600, 800 with a coating material, in accordance with an embodiment of the disclosure. In the illustrated embodiment, nanofiber membrane 600 is positioned on a second frame 612, 812 and placed in a vacuum chamber together a selected coating material. Application of an energy source inside vacuum chamber results in turning the coating material from a solid phase into a gas phase and depositing the gas phase material onto nanofiber membrane 600, 800.

Coating material may be any one of the following: silicon, SiO₂, SiON, boron, ruthenium, boron, zirconium, niobium, molybdenum, rubidium, yttrium, YN, Y₂O₃, strontium, rhodium, metal oxides.

Coating method may be e-beam deposition, chemical vapor deposition, atomic layer deposition, spin coating, dip coating, spray coating, sputtering.

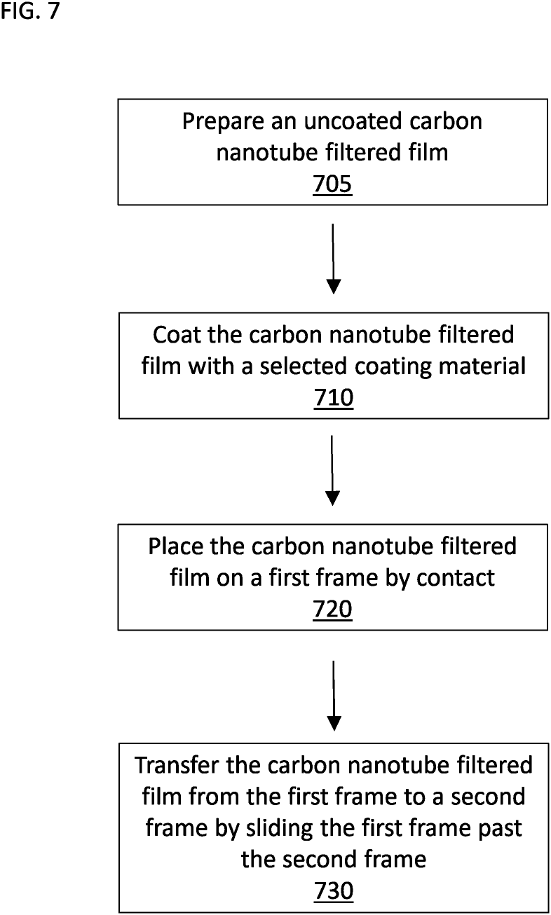

FIG. 7 is a flow chart illustrating steps in a method 700 for transferring a carbon nanotube membrane from a first frame to a second frame, in an embodiment. In a first step 710, a carbon nanotube filtered film is pre-coated with a selected coating material. In a third step 730, the carbon nanotube filtered film is transferred from the first frame to a second frame by sliding the first frame past the second frame.

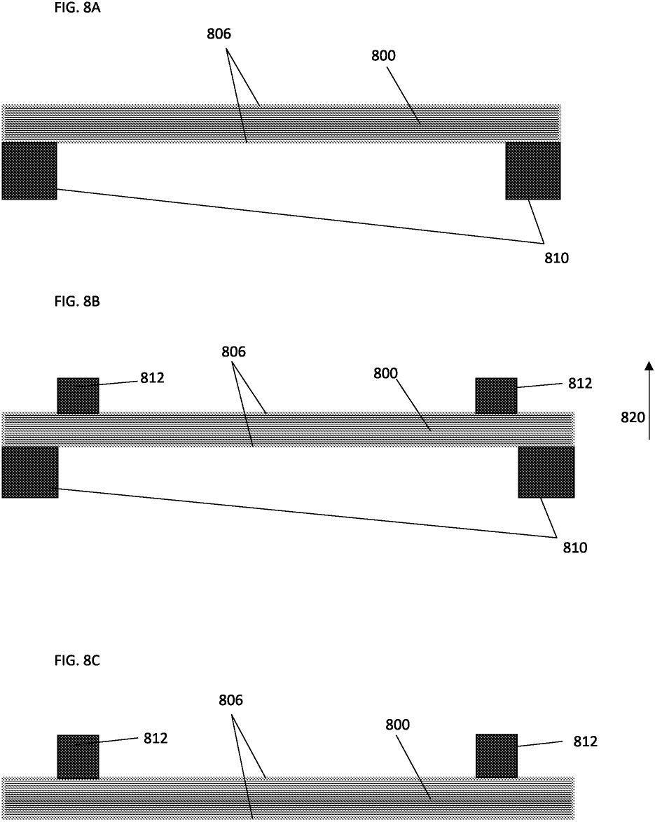

FIG. 8A is a cross-sectional side view of an example carbon nanotube filtered film 800 positioned on a first frame, in an embodiment. In FIG. 8A, carbon nanotube filtered film 800 has a density which is consistent along its length and is coated with a precursor 806.

FIG. 8B is a cross-sectional side view of an example carbon nanotube filtered film 800 positioned on a first frame 810 and a second frame 812, in an embodiment. First frame 810 is slid past second frame 812 along direction 820. Carbon nanotube filtered film 800 adheres to second frame 812 and detaches from first frame 810, as illustrated in FIG. 8C.

Either of method 500 or method 700 can use a wet application (for thick films) or a dry application (for thin films). For the dry application, second frame 612, 812 may be porous to allow stronger adhesion of the carbon nanotube filtered film 600, 800 so as to limit tearing during removal of the first frame 610, 810. For the wet application, second frame 612, 812 may be wetted with a liquid such as water. Next, the film may be applied to the second frame 612, 812 from first frame 610, 810 and the liquid may be allowed to dry prior to removal of first frame 610, 810.

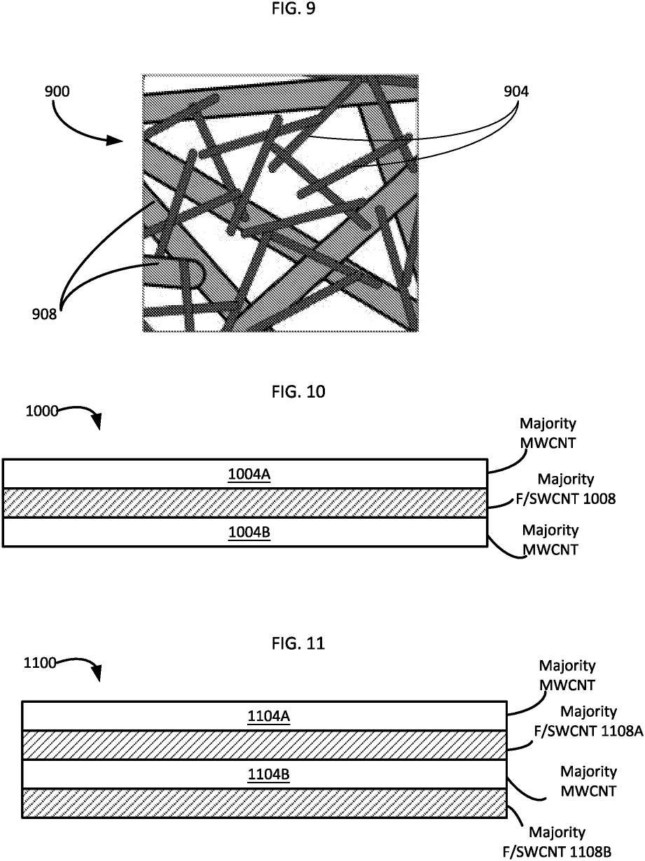

FIG. 9 is a schematic illustration of a composite nanotube filtered film 900, in an example of the present disclosure. As shown, the composite nanotube filtered film 900 includes single/few wall nanotubes 904 that are inter-dispersed with multiwall carbon nanotubes 908. In this example film 900, the single/few wall carbon nanotubes 904 can have at least two beneficial effects on the structure of the film 900 as a whole. For example, the single/few wall carbon nanotubes 904 can increase the number of indirect connections between proximate multiwalled carbon nanotubes 908 by bridging the gaps between them. There interconnections between the short and long nanofibers can improve the transfer and distribution of forces applied to the film and thus improve durability. In a second example of a beneficial effect, the single/few wall carbon nanotubes 904 can decrease a median or mean size of the gaps between adjacent and/or overlapping multiwall carbon nanotubes 908. Furthermore, too many longer multiwalled carbon nanotubes can, when dispersed in a solvent, agglomerate. This can result in a non-uniform film. Shorter nanotubes are more easily dispersed in a solvent and thus are more likely to form a dimensionally uniform film having a uniform density of nanotubes per unit volume.

FIG. 10 is a cross-sectional illustration of one example of a composite nanofiber pellicle 1000, in an example of the present disclosure. As can be seen, the composite nanofiber pellicle 1000 can be composite not only in terms of multiple different types of nanofibers within individual layers but also a composite of multiple layers, each of which includes different ratios of the different types of nanofibers. It will be appreciated that tailoring the composition of each layer individually in a multilayer structure and further tailoring the number and order of layers can affect the emissivity and mechanical durability of embodiments of the present disclosure.

The composite nanofiber pellicle 1000 shown in FIG. 10 includes first and second layers 1004A, 1004B that are on opposing sides of third layer 1008. The composition of first and second layers 1004A, 1004B comprises a majority (e.g., from 50 wt. % to 80 wt. %) of multiwall carbon nanotubes (i.e., nanotubes having from 4 to 20 walls). The composition of the third layer 1008 is that of a majority (e.g., greater than 50 weight percent) of few wall (e.g., nanotubes having from 2 to 3 walls) and/or single wall carbon nanotubes.

The composite nanofiber pellicle 1000 can be formed in any of a variety of ways. For example, a dry mixture of the desired proportion of multiwalled carbon nanotubes and few/single walled carbon nanotubes can be mixed and then suspended in a solvent. In another example, separate suspensions of known concentrations are prepared of multiwalled carbon nanotubes and one or more of few wall carbon nanotubes and single wall nanotubes. The suspensions can then be mixed in proportions to arrive at the desired relative weights of the multiwall, and few/single wall nanotubes in the final filtered film.

When preparing the one or more suspensions, dry carbon nanotubes can be mixed with the solvent to uniformly distribute the nanotubes in the solvent as a suspension. Mixing can include mechanical mixing (e.g., using a magnetic stir bar and stirring plate), ultrasonic agitation (e.g., using an immersion ultrasonic probe) or other means. In some examples the solvent can be water, isopropyl alcohol (IPA), N-Methyl-2-pyrrolidone (NMP), dimethyl sulfide (DMS), and combinations thereof. In some examples a surfactant can also be included to aid the uniform dispersion of carbon nanofibers in the solvent. Example surfactants include, but are not limited to, sodium cholate, sodium dodecyl sulfate (SDS), and sodium dodecyl benzene sulphonate (SDBS). Weight percentage of surfactant in the solvent can be anywhere between 0.1 weight % to 10 wt. % of solvent. In one embodiment, a mixture of 50 wt. % multiwalled carbon nanotubes and 50 wt. % few/single wall carbon nanotubes can be prepared and suspended in water and optionally with SDS surfactant.

The suspension can then be introduced into a structure that removes the solvent and causes the formation of a film of randomly oriented nanofibers on a substrate. Examples of this process include, but are not limited to, vacuum filtration onto a substrate of filter paper. A frame can then be used to harvest the film, thus depositing the filtered film on the frame. The composite film can then be dried (e.g., using a low humidity environment, heat, vacuum). This process can be repeated to form different films of, optionally, differently composed mixtures of multiwall, few wall, and/or single wall nanotubes.

This example process can be repeated multiple times to produce multiple films of carbon nanotubes. In some examples, individual films (having the same or different proportions of multiwall and few/single walled carbon nanotubes in each film) are stacked on one another to form a multilayer composite film. Stacking two or more films can produce a more uniform stack with more uniform properties. For example, if one film in the stack has a local defect (e.g., a hole or tear), adjacent films in the stack can provide physical continuity and uniformity of the properties that would otherwise be absent at the location of the defect. In some embodiments, a stack can include anywhere from 2 to 10 individual films, each of which can have a same or different composition (that is, a different relative proportion of multiwall to single/few wall carbon nanotubes) from other films in the stack.

In some examples, a stacked film can be exposed a densifying solvent that includes water, IPA, NMP, Dimethylformamide (DMF), toluene, or combinations thereof. Exposure to a densifying solvent can cause the films in a stack to adhere to one another. In some cases, not only do the films in the stack adhere to one another, but they merge so as to become indistinguishable from one another, even when using microscopy techniques to examine a cross-section of the stack. In other words, the densified stack does not have visible or microscopically detectable interfaces between layers.

As shown in FIG. 10, first and second layers 1004A, 1004B are on the exposed surfaces of the pellicle 1000. As described above, the first and second layers 1004A, 1004B are composed of a majority (e.g., between 50 wt. % and 80 wt. %) multiwall carbon nanotubes. As also described above, films formed from multiwall carbon nanotubes have a higher thermal emissivity than those formed from few/single wall nanotubes. Thus configured, the exposed first and second layer 1004A, 1004B can improve the reliability of the pellicle 1000 when used in an environment that includes EUV and/or a vacuum. By emitting thermal energy (formed in the pellicle by the incident radiation) more efficiently than a pellicle composed primarily of few/single wall nanotubes, the pellicle 1000 can better withstand the operating environment in an EUV lithography device. This configuration further reduces the reabsorption of thermal radiation emitted by and/or conducted away from the pellicle 1000.

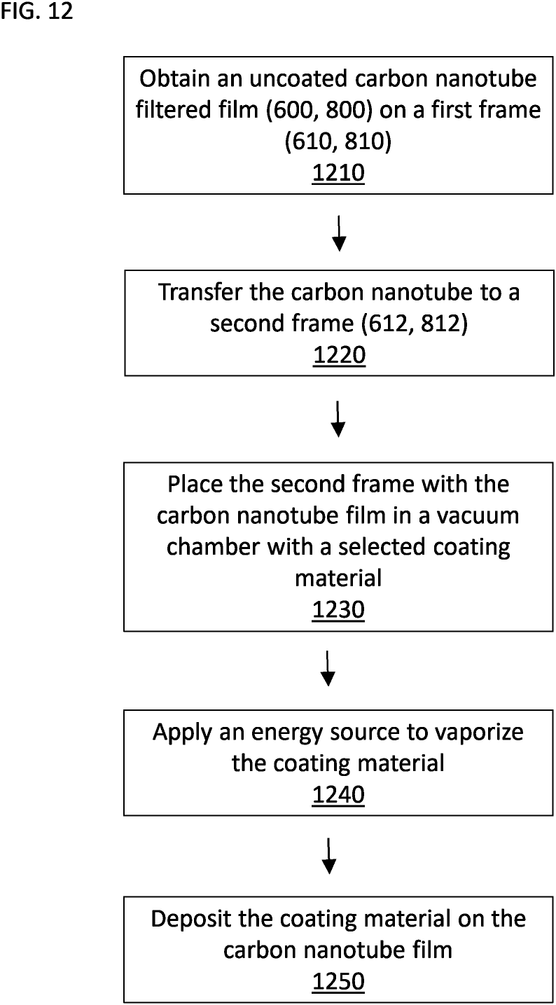

FIG. 11 illustrates an alternative embodiment of a composite nanofiber pellicle 1100 formed from a stack of filtered carbon nanotube films. Similar to the pellicle 1000, the pellicle 1100 includes first and second layers 1104A, 1104B that are formed primarily from multiwall carbon nanotubes. Third and fourth layers 1108A, 1108B are formed primarily from single/few wall carbon nanotubes.

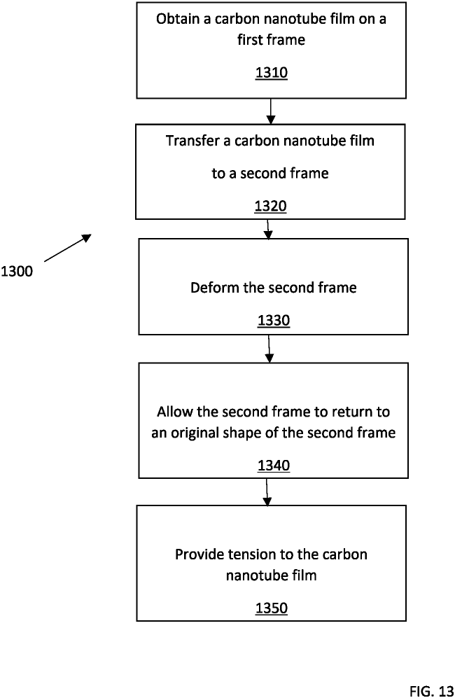

FIG. 13 illustrates an example method for controlling tension of a nanofiber membrane 600, 800. In step 1310, a carbon nanotube film is placed on first frame 610, 810 (i.e. transfer frame, illustrated in FIGS. 6A-C and 8A-C). In step 1320, the carbon nanotube film is transferred to second frame 612, 812 (i.e. final frame, illustrated in FIGS. 6B-C and 8B-C). In step 1330, second frame 612, 812 is deformed. Second frame 612, 812 may be deformed by either a thermal method or a physical method. Second frame 612, 812 may be deformed between 0.5% and 5%, between 1% and 4%, between 2% and 3%, between 0.5% and 3%, or between 3% and 5%. In some embodiments, first frame 610, 810 may be deformed similarly. For example, the first frame 610, 810 may be deformed by either a thermal method or a physical method. The first frame 610, 810 may be deformed between 0.5% and 5%, between 1% and 4%, between 2% and 3%, between 0.5% and 3%, or between 3% and 5%. The film cannot be over-tensed as it will reach a breaking point and rupture. Thus, care must be taken to effect expansion and contraction of the frame within a reasonable range. In step 1340, second frame 612, 812 is allowed to return to an original shape of second frame 612, 812. In step 1350, tension is provided to the carbon nanotube film 600, 800. This same procedure may be applicable to the first frame 610, 810 and carbon nanotube film 600, 800.

The tension imparted to the film 600, 800 by deforming the first frame 610, 810 and/or the second frame 612, 812 improves various characteristics of the film. For example, in the case of carbon nanotubes, which are capable of having very high aspect ratios (ratio of length to diameter) with some as high as 132,000,000:1 or more, the aspect ratio can be finely tuned/adjusted to satisfy a particular use or application without damaging a film made of such carbon nanotubes. As a result of the tension imparted to the film 600, 800, the length and the diameter of the carbon nanotubes may be adjusted for a particular use or application. By imparting tension to the film, the carbon nanotubes can be finely tuned/adjusted to provide the film with a transmittance of incident irradiation as high as above 90% or above 95%. The emissivity may also be finely tuned/adjusted.

Unintentional damage to the film 600, 800 that may result from over-tensioning is inhibited by deforming the first frame 610, 810 and/or the second frame 612, 812 as described above, i.e., since the tension may be imparted indirectly to the film 600, 800 via deformation of the first frame 610, 810 and/or the second frame 612, 812. Additionally, since the first frame 610, 810 and/or the second frame 612, 812 may be provided with larger dimensions (e.g., the frame may be larger in length, width and/or thickness, thereby making it easier to grasp or grip the frame without unintentionally damaging the comparatively more delicate film) than the film 600, 800, applying the deformation to the first frame 610, 810 and/or the second frame 612, 812 makes it possible and easier to control the tension imparted to the film and also mitigates damage to the film (for example, in comparison to directly applying tension to the film itself). The opacity, mechanical strength, flexibility, thermal conductivity, electrical conductivity, and hydrophobicity may all be adjusted by imparting tension to the film 600, 800 as a result of deforming the first frame 610, 810 and/or the second frame 612, 812. The tensioning of the film 600, 800 as described above may be useful in EUV applications in which the film is provided as a pellicle.

It should be appreciated that the film may be secured to the frame via van der Waals forces. The film may also be secured and/or adhered to the frame by, for example, creating a capillary force between the film and frame by applying a liquid/mist to the surface of the frame prior to film transfer. For example, a method may include securing a carbon nanotube membrane to a frame and deforming the frame to impart tension to the carbon nanotube membrane. The method may include subjecting the frame to thermal treatment to deform the frame and impart the tension to the carbon nanotube membrane. The method may include subjecting the frame to compression or expansion to deform the frame and impart the tension to the carbon nanotube membrane. Also, the carbon nanotube membrane may include a plurality of intersecting carbon nanotubes having an initial deflection with a first deflection value The method may also include tensioning the plurality of carbon nanotubes by deforming the frame so as to obtain a tensioned deflection with a second deflection value. The second deflection value may be smaller than the first deflection value. It should be appreciated that the test for measure the first deflection value and the second deflection value is not limited. However, in comparing the first deflection value to a second deflection value the values should be arrived at using a same test method for measurement. Of course, the first deflection value and the second deflection value may be measured in accordance with a bulge test or burst test described below or any other suitable test for meaning deflection.

A deflection of the film may be measured by a “bulge test” and “burst test”. The “bulge test” and “burst test” quantifies an amount of deflection the film is able to undergo without rupturing and at rupture. This measure is at least in part a result of the tension imparted to the film by deformation of the frame(s). For example, in measuring the deflection, a film (that has been imparted with tension), or other membrane comprising the film, may be attached to a supporting member (for example, in the form of a planar or flat border having a central opening). A reference plane may be established or identified at a position coinciding with a planar contact interface between the film and the supporting member. The supporting member may have a central opening over which a corresponding central region of the film spans. An initial stream of inert gas may be applied to the central region of the film at a low steady pressure (for example, aimed perpendicular to a plane of the central region of the film), thereby causing the central region of the film to be raised a height (h) from the reference plane. The gas pressure may be continuously increased at regular or equal increments to deform the film further until the pressure reaches a predetermined value, which may be 2 pascal for a “2 Pa bulge test”. When the pressure reaches the predetermined pressure (for example, 2 pascal), a distance from the reference plane to a maximum height (h ₘₐₓ) of the deformed film is defined as the maximum deflection height at the predetermined pressure (for example, 2 pascal). The pressure of the gas can be increased beyond, for example, the 2 pascal pressure until the film ruptures or bursts. The pressure at which the film ruptures is the rupture pressure. The membrane deflection at which rupture occurs is the rupture deflection or rupture height.

The deflection test may be performed for various films under various applied gas pressures depending upon the desired use or application of the film. For example, various sizes of film range from 1 cm × 1 cm up to 12 cm × 15 cm. The film may have any suitable size depending upon the desired use and application. The deflection test is not limited by the size of the film as the desired parameters such as maximum deflection height, rupture deflection and a pressure of the gas may be adjusted proportionally based upon the size of the film or the desired use and application. Alternatively, it should be appreciated that the deflection test may employ a vacuum pressure to cause the measured deflection at a predetermined vacuum pressure. For example, a vacuum pressure that changes at a maximal speed of preferably 3.5 mbar/sec., up to 5 mbar/sec. may be applied to the film to measure a maximum deflection height.

Tension may be imparted to the film such that a 1 cm x 1 cm film deflects a maximum height (h ₘₐₓ) of 0.4 cm, and more preferably 0.3 cm, and even more preferably 0.2 cm, and even more preferably 0.1 cm when a gas pressure of 2 pascal is applied perpendicular to a plane of the film. The maximum deflection height may be as small as .01 cm depending upon the application. A 1 cm x 1 cm film having the preceding maximum deflection heights exhibit, for example, aspect ratios and other characteristics as a result of the tensioning. The deflection as a ratio (h ₘₐₓ / d ₘₐₓ) of the maximum deflection height (h ₘₐₓ) of the film to a maximum dimension (d ₘₐₓ) of the film (for example, a maximum length, diameter, etc. being the maximum dimension d ₘₐₓ) may be in a range of about 0.0025 to 0.0400 and is film size-dependent.

It should be appreciated that other applied pressures are within the spirit of the present disclosure. For example, a film may undergo a ratio (h ₘₐₓ / d ₘₐₓ) the maximum deflection height (h ₘₐₓ) of the film to a maximum dimension (d ₘₐₓ), or a vacuum pressure flow rate of about 10 sccm, or under 3.5 mbar/second pressure change, or any other conditions in an EUV lithography scanner.

A film may undergo EUV transmittance improvement by the frame deformation disclosed herein.

In a thermal method of deforming second frame 612, 812, second frame 612, 812 is cooled to provide a shrinking effect. Second frame 612, 812 is then allowed to return to an original shape of second frame 612, 812 by warming second frame 612, 812 up to room temperature, thus providing tension to carbon nanotube film 600, 800.

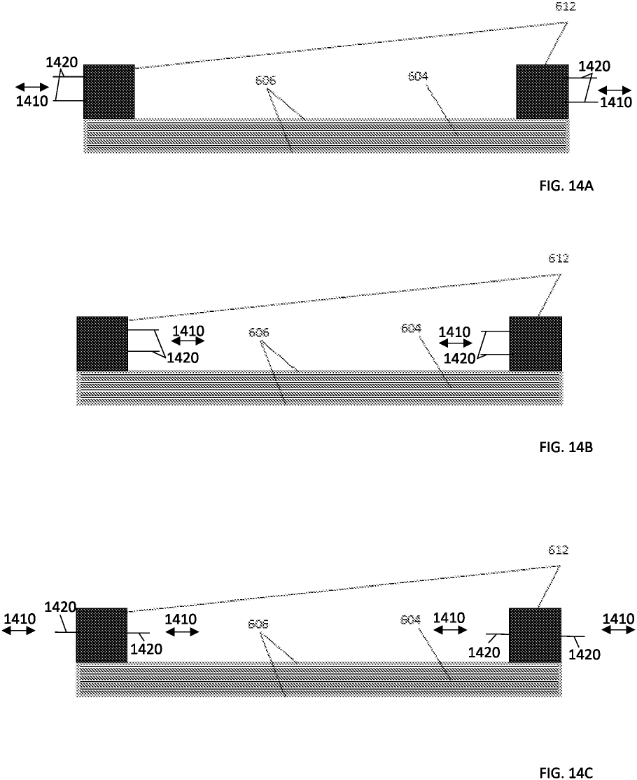

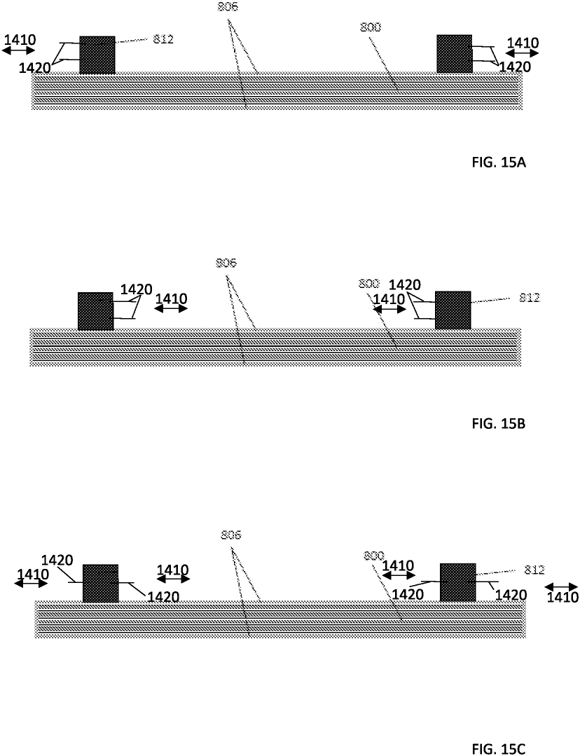

In a physical method of deforming second frame 612, 812, a set of pins 1420 are used to push or pull the sides of the second frame inwards. In some embodiments (illustrated in FIGS. 14A-C and 15A-C), four pins 1420 are used to push or pull the sides of the second frame inwards along direction 1410. In some embodiments, the physical method pushes or pulls the sides inwards but not the corners. The physical method may not provide as much uniformity of deformation as the thermal method but may be faster.

Advantages are provided by the apparatus and method disclosed herein. Specifically, a carbon nanotube film 600, 800 tensed by the described methods can be used in EUV applications, described above, as a pellicle. A tensed film can provide less deflection than an un-tensed version of the same film.

The amount a given frame will shrink can be estimated. Hooke’s Law can be applied in order to determine the tension force that will be applied to the film. The film can be considered equivalent to a simple helical spring that has one end attached to some fixed object, while the free end is being pulled by a force whose magnitude is Fₛ. Suppose that the spring has reached a state of equilibrium, where its length is not changing anymore. Let x be the amount by which the free end of the spring was displaced from its “relaxed” position (when it is not being stretched). Hooke’s law states that

$$\left({F}_{s} = k x\right)$$

where k is a positive real number, characteristic of the spring.

Young’s modulus enables the calculation of the change in the dimension of a film made of an isotropic elastic material under tensile or compressive loads. For instance, it can used to predict how much the film extends under tension or shortens under compression. Young’s modulus directly applies to cases of uniaxial stress, that is tensile or compressive stress in one direction and no stress in the other directions.

Young’s modulus E, can be calculated by dividing the tensile stress, σ(ε), by the engineering extensional strain, ε, in the elastic (initial, linear) portion of the physical stress-strain curve:

$$E = \frac{σ \left(ε\right)}{ε} = \frac{F / A}{\text{Δ} L / {L}_{0}} = \frac{F {L}_{0}}{A \text{Δ} L}$$

where E is the Young’s modulus (modulus of elasticity), F is the force exerted on the film under tension, A is the actual cross-sectional area of the film, which equals the area of the cross-section perpendicular to the applied force, ΔL is the amount by which the length of the film changes (ΔL is positive if the film is stretched, and negative when the film is compressed), and L₀ is the original length of the film.

Tension can alternatively be measured by a deflection method using pressure. A small amount of pressure can be applied to the film and the amount of deflection of the film can be measured to determine tension.

### Further Considerations

The foregoing description of the embodiments of the disclosure has been presented for the purpose of illustration; it is not intended to be exhaustive or to limit the claims to the precise forms disclosed. Persons skilled in the relevant art can appreciate that many modifications and variations are possible in light of the above disclosure.

The language used in the specification has been principally selected for readability and instructional purposes, and it may not have been selected to delineate or circumscribe the inventive subject matter. It is therefore intended that the scope of the disclosure be limited not by this detailed description, but rather by any claims that issue on an application based hereon. Accordingly, the disclosure of the embodiments is intended to be illustrative, but not limiting, of the scope of the invention, which is set forth in the following claims.

What is claimed is:

1. A method, comprising:
providing a first frame, wherein the first frame has an opening that is enclosed by an inner periphery of the first frame;
securing a carbon nanotube membrane to the first frame so as to span the opening; and
deforming the first frame to impart tension to the carbon nanotube membrane.

2. The method of claim 1, comprising:
subjecting the first frame to thermal treatment to deform the first frame and impart the tension to the carbon nanotube membrane.

3. The method of claim 1, comprising:
subjecting the first frame to compression or expansion to deform the first frame and impart the tension to the carbon nanotube membrane.

4. The method of claim 1, wherein the carbon nanotube membrane includes a plurality of intersecting carbon nanotubes having an initial deflection with a first deflection value; and
tensioning the plurality of carbon nanotubes by deforming the frame so as to obtain a tensioned deflection with a second deflection value, wherein the second deflection value and the first deflection value are different from each other.

5. The method of claim 1 further comprising:
providing a second frame;
placing the second frame in direct contact with the carbon nanotube membrane; and
separating the carbon nanotube membrane from the first frame.

6. The method of claim 5, wherein:
the second frame is provided to be smaller than the opening of the first frame; and
separating the carbon nanotube membrane from the first frame by forcibly passing the second frame through the opening of the first frame.

7. The method of claim 5, wherein:
the surface of the second frame is covered by a layer of liquid selected from water, surfactant prior to carbon nanotube membrane transfer.

8. The method of claim 5, further comprising:
removing access carbon nanotube membrane on the first frame but not on the second frame by a method selected from laser treatment, electrical discharge machine, blade cutting.

9. The method of claim 4, wherein the second deflection value is less than the first deflection value.

10. The method of claim 4, wherein the second deflection value is greater than the first deflection value.

11. A method, comprising:
positioning a carbon nanotube membrane on a first frame;
a second frame on the carbon nanotube membrane;
transferring the carbon nanotube membrane to the second frame;
providing a first deformation to the second frame; and
providing a second deformation to the second frame.

12. The method of claim 11, wherein the first deformation comprises shrinking.

13. The method of claim 12, wherein the second deformation comprises enlarging.

14. The method of claim 11, wherein at least one of the first deformation and the second deformation change the size of the second frame by between 0.5% and 5%.

15. The method of claim 12, wherein the first deformation comprises cooling the second frame.

16. The method of claim 13, wherein the second deformation comprises warming the second frame.

17. The method of claim 12, wherein the first deformation comprises utilizing a set of pins attached to the second frame that are pushed or pulled inward.

18. The method of claim 13, wherein the second deformation comprises utilizing a set of pins attached to the second frame that are pushed or pulled outward.

19. The method of claim 11, wherein transferring the carbon nanotube membrane to the second frame is achieved by lifting the first frame off of the carbon nanotube membrane.

20. The method of claim 11, wherein transferring the carbon nanotube membrane to the second frame is achieved by sliding the first frame past the second frame.

21. The method of claim 11, wherein the carbon nanotube membrane is configured with increased tension following the first deformation and the second deformation.

22. The method of claim 21, wherein the carbon nanotube membrane is configured with decreased deflection following the first deformation and the second deformation.

23. The method according to claim 1, wherein the carbon nanotube membrane is a carbon nanotube filtered film.
